(19) United States
(12) Patent Application Publication
(10) Pub. No.: US 2022/0157748 A1
(43) Pub. Date: May 19, 2022

(54) RADIO FREQUENCY MODULE

(71) Applicant: Murata Manufacturing Co., Ltd., Kyoto (JP)

(72) Inventors: Mayuka ONO, Kyoto (JP); Motoji TSUDA, Kyoto (JP); Fumio HARIMA, Kyoto (JP); Koshi HIMEDA, Kyoto (JP); Hiroaki TOKUYA, Kyoto (JP)

(21) Appl. No.: 17/649,287

(22) Filed: Jan. 28, 2022

Related U.S. Application Data
(63) Continuation of application No. PCT/JP2020/024437, filed on Jun. 22, 2020.

(30) Foreign Application Priority Data
Aug. 20, 2019 (JP) 2019-150637

(51) Int. Cl. H01L 23/66; H01L 23/12; H01L 23/31; H01L 25/065; H05K 1/18; H01L 23/498

(52) U.S. Cl. CPC H01L 23/66; H01L 23/12; H01L 23/3192; H01L 25/065; H04B 1/04; H01L 23/49816; H01L 2223/6644; H01L 2223/6605; H05K 1/181

(57) ABSTRACT

A mounting substrate has one main surface (a first main surface). An electronic component has a first face, a second face, and a side face, and is provided on the one main surface of the mounting substrate. A solder bump is disposed between the mounting substrate and the electronic component, and electrically connects the mounting substrate and the electronic component. A resin layer is provided on the one main surface of the mounting substrate to cover the electronic component. The first face is a face of the electronic component at a side opposite to the mounting substrate. The side face of the electronic component is in contact with the resin layer. A space is provided between at least a part of the first face and the resin layer in a thickness direction of the mounting substrate.

### CROSS REFERENCE TO RELATED APPLICATIONS

This is a continuation of International Application No. PCT/JP2020/024437 filed on Jun. 22, 2020 which claims priority from Japanese Patent Application No. 2019-150637 filed on Aug. 20, 2019. The contents of these applications are incorporated herein by reference in their entireties.

### BACKGROUND OF THE DISCLOSURE

### Field of the Disclosure

The present disclosure relates generally to a radio frequency module, and more particularly to a radio frequency module including a resin layer covering an electronic component.

### Description of the Related Art

Conventionally, radio frequency modules (transmission/reception modules) to be used in mobile communication terminals such as cellular phones have been known (for example, see Patent Document 1). A radio frequency module described in Patent Document 1 includes a mounting substrate (wiring substrate), electronic components (a low-noise amplifier and a power amplifier), and a resin layer (insulating resin). The mounting substrate has one main surface (first surface). Surface connection mounting between the electronic components and the one main surface of the mounting substrate is a flip-chip connection mounting. The resin layer is formed so as to cover the electronic components.

Patent Document 1: Japanese Unexamined Patent Application Publication No. 2018-98677

### BRIEF SUMMARY OF THE DISCLOSURE

In the radio frequency module described in Patent Document 1, since the entire electronic component is in contact with the resin layer, it is difficult for the electronic component to be separated from the mounting substrate, but there is a problem in that the stress applied to the electronic component increases when the radio frequency module is mounted on an external substrate.

It is an object of the present disclosure to provide a radio frequency module capable of reducing the stress applied to an electronic component when the radio frequency module is mounted on an external substrate while suppressing the separation of the electronic component from a mounting substrate.

A radio frequency module according to one aspect of the present disclosure includes a mounting substrate, an electronic component, a solder bump, and a resin layer. The mounting substrate has one main surface. The electronic component has a first face and a second face that are opposed to each other and a side face intersecting with the first face and the second face, and is provided on the one main surface of the mounting substrate. The solder bump is disposed between the mounting substrate and the electronic component and electrically connects the mounting substrate and the electronic component. The resin layer is provided on the one main surface of the mounting substrate so as to cover the electronic component. The first face is a face of the electronic component at a side opposite to the mounting substrate. The side face of the electronic component and the resin layer are in contact with each other. A space is provided between at least a part of the first face and the resin layer in a thickness direction of the mounting substrate.

According to the radio frequency module of the above-described aspect of the present disclosure, it is possible to reduce the stress applied to the electronic component when the radio frequency module is mounted on an external substrate while suppressing the separation of the electronic component from the mounting substrate.

### BRIEF DESCRIPTION OF THE SEVERAL VIEWS OF THE DRAWINGS

FIG. 1 is a plan view of a radio frequency module according to an embodiment.

FIG. 2 is a cross-sectional view taken along the line X1-X1 of FIG. 1.

FIG. 3 is a cross-sectional view of an electronic component to be used in the same radio frequency module as that described above.

FIG. 4 is a cross-sectional view of a radio frequency module according to Modification 1 of the embodiment.

FIG. 5 is a cross-sectional view of a radio frequency module according to Modification 2 of the embodiment.

FIG. 6 is a cross-sectional view of a radio frequency module according to Modification 3 of the embodiment.

### DETAILED DESCRIPTION OF THE DISCLOSURE

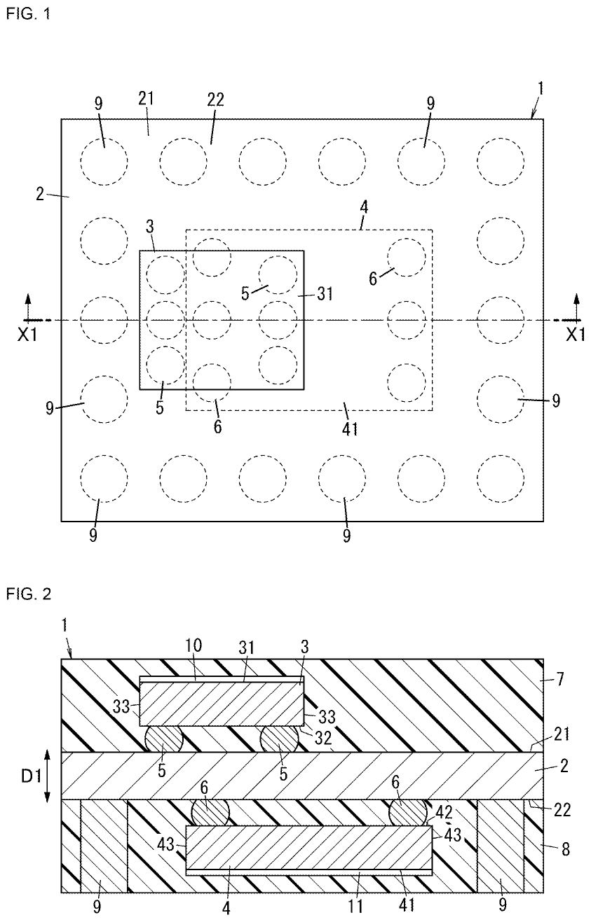

Hereinafter, a radio frequency module according to an embodiment will be described with reference to the drawings. FIG. 1 to FIG. 6 referred to in the following embodiment and the like are schematic diagrams, and ratios of sizes and thicknesses of the respective constituent elements in the diagrams do not necessarily reflect actual dimensional ratios.

### Embodiment

(1) Configuration of Radio Frequency Module

A configuration of a radio frequency module 1 according to the present embodiment will be described with reference to FIG. 1 to FIG. 3.

The radio frequency module 1 according to the present embodiment is used in, for example, a communication device. The communication device is, for example, a cellular phone such as a smartphone. Note that the communication device is not limited to a cellular phone, and may be, for example, a wearable terminal such as a smart watch.

The radio frequency module 1 can be electrically connected to an external substrate (not illustrated). The external substrate corresponds to, for example, a mother substrate of a cellular phone or a communication device. Here, a case where the radio frequency module 1 can be electrically connected to the external substrate includes not only a case where the radio frequency module 1 is directly mounted on the external substrate but also a case where the radio frequency module 1 is indirectly mounted on the external substrate. Further, the case where the radio frequency module 1 is indirectly mounted on the external substrate includes a case where the radio frequency module 1 is mounted on another radio frequency module mounted on the external substrate and the like.

As illustrated in FIG. 1 and FIG. 2, the radio frequency module 1 according to the present embodiment includes a mounting substrate 2, electronic components 3 and 4, a plurality of solder bumps 5 and 6, and resin layers 7 and 8. Further, the radio frequency module 1 includes a plurality of external connection terminals 9.

(1.1) Mounting Substrate

The mounting substrate 2 has a first main surface 21 and a second main surface 22 that are opposed to each other in a thickness direction D1 of the mounting substrate 2.

The mounting substrate 2 is, for example, a printed wiring board, a low temperature co-fired ceramics (LTCC) substrate, a high temperature co-fired ceramics (HTCC) substrate, or a resin multilayer substrate. In other words, the mounting substrate 2 is a printed circuit board or a ceramic substrate.

Here, the mounting substrate 2 is, for example, a multilayer substrate including a plurality of dielectric layers and a plurality of conductive layers. The plurality of dielectric layers and the plurality of conductive layers are laminated in the thickness direction D1 of the mounting substrate 2. Each of the plurality of conductive layers is formed in a predetermined pattern. Each of the plurality of conductive layers includes one or a plurality of conductor portions in one plane orthogonal to the thickness direction D1 of the mounting substrate 2. A material of each conductive layer is, for example, copper. The plurality of conductive layers includes a ground layer. In the radio frequency module 1, the plurality of ground terminals and the ground layer are electrically connected to each other through a via conductor or the like included in the mounting substrate 2.

The mounting substrate 2 is not limited to a printed wiring board, an LTCC substrate, an HTCC substrate, or a resin multilayer substrate, and may be a wiring structure. The wiring structure is, for example, a multilayer structure. The multilayer structure includes at least one insulating layer and at least one conductive layer. The insulating layer is formed in a predetermined pattern. When a plurality of insulating layers is provided, the plurality of insulating layers is formed in a predetermined pattern determined for each layer. The conductive layer is formed in a predetermined pattern different from the predetermined pattern of the insulating layer. When a plurality of conductive layers is provided, the plurality of conductive layers is formed in a predetermined pattern determined for each layer. The conductive layer may include one or more rewiring portions. In the wiring structure, a first surface of two surfaces that are opposed to each other in the thickness direction of the multilayer structure is the first main surface 21 of the mounting substrate 2, and a second surface of the two surfaces is the second main surface 22 of the mounting substrate 2. The wiring structure may be, for example, an interposer. The interposer may be an interposer using a silicon substrate, or may be a substrate configured of multiple layers.

The electronic component 3 is disposed on the first main surface 21 of the mounting substrate 2. The electronic component 4 and the plurality of external connection terminals 9 are disposed on the second main surface 22 of the mounting substrate 2. Here, in the present embodiment, the first main surface 21 is one main surface.

(1.2) Electronic Components

As illustrated in FIG. 2, the electronic component 3 is disposed on the first main surface 21 of the mounting substrate 2. The electronic component 3 is, for example, a power amplifier. The power amplifier is an amplifier that amplifies a transmission signal to be transmitted to the outside through an antenna. The power amplifier is controlled by, for example, a power amplifier controller.

As illustrated in FIG. 2, the electronic component 3 has a first face 31, a second face 32, and a plurality of side faces 33. The first face 31 and the second face 32 are opposed to each other in the thickness direction D1 of the mounting substrate 2. That is, a direction in which the first face 31 and the second face 32 are opposed to each other is the thickness direction D1 of the mounting substrate 2. Each of the plurality of side faces 33 intersects (is orthogonal to) the first face 31 and the second face 32. The second face 32 faces the first main surface 21 of the mounting substrate 2 when the electronic component 3 is provided on the mounting substrate 2. That is, the first face 31 of the electronic component 3 is a face of the electronic component 3 at an opposite side to the mounting substrate 2.

As illustrated in FIG. 2, the electronic component 4 is disposed on the second main surface 22 of the mounting substrate 2. The electronic component 4 is, for example, a low-noise amplifier. The low-noise amplifier is an amplifier that amplifies a reception signal received from the outside through an antenna with low noise.

As illustrated in FIG. 2, the electronic component 4 includes a first face 41, a second face 42, and a plurality of side faces 43. The first face 41 and the second face 42 are opposed to each other in the thickness direction D1 of the mounting substrate 2. That is, a direction in which the first face 41 and the second face 42 are opposed to each other is the thickness direction D1 of the mounting substrate 2. Each of the plurality of side faces 43 intersects (is orthogonal to) the first face 41 and the second face 42. The second face 42 faces the second main surface 22 of the mounting substrate 2 when the electronic component 4 is provided on the mounting substrate 2. That is, the first face 41 of the electronic component 4 is a face of the electronic component 4 at an opposite side to the mounting substrate 2.

(1.3) Solder Bumps

The solder bump 5 is a terminal for electrically connecting the mounting substrate 2 and the electronic component 3. As illustrated in FIG. 2, the solder bump 5 is disposed between the electronic component 3 and the mounting substrate 2 in the thickness direction D1 of the mounting substrate 2. The electronic component 3 is mounted on the first main surface 21 of the mounting substrate 2 with a plurality of solder bumps 5 interposed therebetween. That is, the electronic component 3 is flip-chip mounted on the first main surface 21 of the mounting substrate 2 with the solder bumps 5 interposed therebetween.

The solder bump 6 is a terminal for electrically connecting the mounting substrate 2 and the electronic component 4. As illustrated in FIG. 2, the solder bump 6 is disposed between the electronic component 4 and the mounting substrate 2 in the thickness direction D1 of the mounting substrate 2. The electronic component 4 is mounted on the second main surface 22 of the mounting substrate 2 with a plurality of solder bumps 6 interposed therebetween. That is, the electronic component 4 is flip-chip mounted on the second main surface 22 of the mounting substrate 2 with the solder bumps 6 interposed therebetween.

(1.4) Resin Layer

As illustrated in FIG. 2, the resin layer 7 is provided on the first main surface 21 of the mounting substrate 2 and covers the first main surface 21 and the electronic component 3 disposed on the first main surface 21. The resin layer 7 has a function of ensuring reliability such as mechanical strength (impact resistance) and moisture resistance of the electronic component 3 disposed on the first main surface 21. That is, the resin layer 7 has a function of protecting the electronic component 3 disposed on the first main surface 21.

As illustrated in FIG. 2, the resin layer 8 is provided on the second main surface 22 of the mounting substrate 2 and covers the second main surface 22 and the electronic component 4 disposed on the second main surface 22. The resin layer 8 has a function of ensuring reliability such as mechanical strength (impact resistance) and moisture resistance of the electronic component 4 disposed on the second main surface 22. That is, the resin layer 8 has a function of protecting the electronic component 4 disposed on the second main surface 22.

The resin layers 7 and 8 include, for example, epoxy resin, phenol resin, urethane resin, or polyimide. Note that the resin layers 7 and 8 may contain a filler or the like as appropriate.

Here, in the radio frequency module 1 according to the present embodiment, as illustrated in FIG. 2, a space 10 is provided between the first face 31 of the electronic component 3 and the resin layer 7 in the thickness direction D1 of the mounting substrate 2. In the present embodiment, the space 10 is provided between the entire first face 31 and the resin layer 7, but it is sufficient that the space 10 is provided between at least a part of the first face 31 and the resin layer 7. In this case, it is preferable that at least a part of the first face 31 overlap the solder bump 5 in a plan view from the thickness direction D1 of the mounting substrate 2. The space 10 is formed between the first face 31 of the electronic component 3 and the resin layer 7 by, for example, mirror-finishing the first face 31 of the electronic component 3 and then forming the resin layer 7.

Also, in the radio frequency module 1 according to the present embodiment, as illustrated in FIG. 2, a space 11 is provided between the first face 41 of the electronic component 4 and the resin layer 8 in the thickness direction D1 of the mounting substrate 2. In the present embodiment, the space 11 is provided between the entire first face 41 and the resin layer 8, but it is sufficient that the space 11 is provided between at least a part of the first face 41 and the resin layer 8. In this case, it is preferable that at least a part of the first face 41 overlap the solder bump 6 in a plan view from the thickness direction D1 of the mounting substrate 2. The space 11 is formed between the first face 41 of the electronic component 4 and the resin layer 8 by, for example, mirror-finishing the first face 41 of the electronic component 4 and then forming the resin layer 8.

Further, in the radio frequency module 1 according to the present embodiment, as illustrated in FIG. 2, the side face 33 of the electronic component 3 and the resin layer 7 are in contact with each other, and the side face 43 of the electronic component 4 and the resin layer 8 are in contact with each other.

(1.5) External Connection Terminals

The plurality of external connection terminals 9 are terminals for electrically connecting the mounting substrate 2 and an external substrate (not illustrated). The plurality of external connection terminals 9 include an input terminal, an output terminal, a ground terminal, and the like of the radio frequency module 1.

The plurality of external connection terminals 9 are disposed on the second main surface 22 of the mounting substrate 2. The plurality of external connection terminals 9 are columnar (for example, cylindrical) electrodes provided on the second main surface 22 of the mounting substrate 2. A material of the plurality of external connection terminals 9 is, for example, metal such as copper or a copper alloy. Each of the plurality of external connection terminals 9 has a base end portion bonded to the second main surface 22 of the mounting substrate 2 and a tip end portion at an opposite side to the base end portion in the thickness direction D1 of the mounting substrate 2. The tip end portion of each of the plurality of external connection terminals 9 may include, for example, a gold plating layer.

The radio frequency module 1 is provided with a plurality of external connection terminals 9 from the viewpoints of mountability of the radio frequency module 1 on an external substrate, increasing the number of ground terminals of the radio frequency module 1, and the like.

(2) Structure of Electronic Component

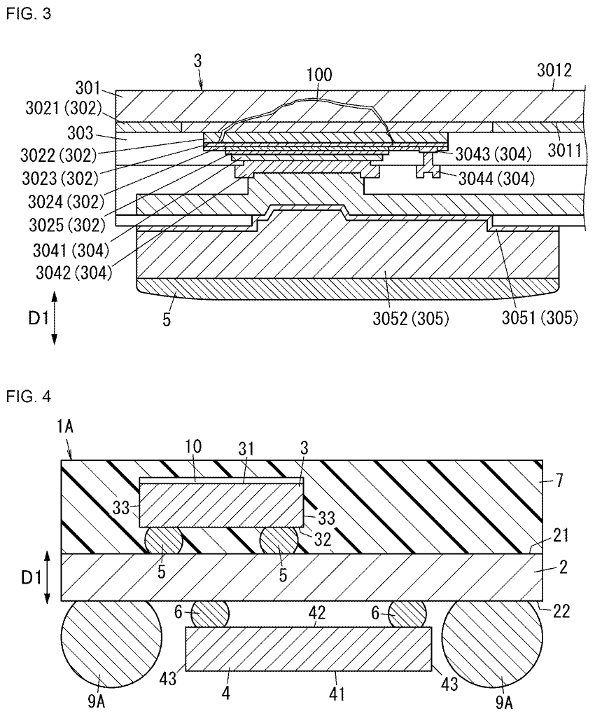

Next, a structure of the electronic component 3 will be described with reference to FIG. 3.

As illustrated in FIG. 3, the electronic component 3 includes a substrate 301, a functional portion 302, an insulating film 303, a pad electrode 304, and a columnar electrode 305.

(2.1) Substrate

As illustrated in FIG. 3, the substrate 301 has a first main surface 3011 and a second main surface 3012. The first main surface 3011 and the second main surface 3012 are opposed to each other in the thickness direction D1 of the substrate 301 (the thickness direction of the mounting substrate 2). The substrate 301 contains, for example, gallium arsenide (GaAs). Note that the substrate 301 may contain, for example, silicon germanium (SiGe), silicon (Si), silicon carbide (SiC), or gallium nitride (GaN).

(2.2) Functional Portion

The functional portion 302 configures some of functions of the radio frequency module 1. The functional portion 302 is, for example, a GaAs-based heterojunction bipolar transistor (HBT). The functional portion 302 is provided on the first main surface 3011 of the substrate 301. As illustrated in FIG. 3, the functional portion 302 includes a sub-collector layer 3021, a collector layer 3022, a base layer 3023, an emitter layer 3024, and an emitter mesa layer 3025.

In the functional portion 302, the sub-collector layer 3021, the collector layer 3022, the base layer 3023, the emitter layer 3024, and the emitter mesa layer 3025 are laminated in this order from the substrate 301 side in the thickness direction D1 of the substrate 301.

Note that although the functional portion 302 is provided on the substrate 301 in the radio frequency module 1 according to the present embodiment, the functional portion may be included in the substrate. In this case, a portion of the substrate excluding the functional portion serves as a base portion.

(2.3) Insulating Film

The insulating film 303 has electrical insulating properties. The insulating film 303 is formed on the substrate 301 so as to cover the functional portion 302 provided on the substrate 301. A material of the insulating film 303 is, for example, synthetic resin such as epoxy resin or polyimide.

(2.4) Pad Electrode

As illustrated in FIG. 3, the pad electrode 304 includes an emitter electrode 3041, an emitter wiring line 3042, a base electrode 3043, and a base wiring line 3044.

The emitter electrode 3041 and the emitter wiring line 3042 are laminated in the order of the emitter electrode 3041 and the emitter wiring line 3042 from the substrate 301 side in the thickness direction D1 of the substrate 301. In addition, the base electrode 3043 and the base wiring line 3044 are laminated in the order of the base electrode 3043 and the base wiring line 3044 from the substrate 301 side in the thickness direction D1 of the substrate 301.

The pad electrode 304 is electrically connected to the functional portion 302 through the emitter electrode 3041 and the base electrode 3043.

(2.5) Columnar Electrode

The columnar electrode 305 is an electrode for electrically connecting the pad electrode 304 and the solder bump 5. The columnar electrode 305 includes an under bump metal layer 3051 and a metal post 3052.

The under bump metal layer 3051 and the metal post 3052 are laminated in the order of the under bump metal layer 3051 and the metal post 3052 from the substrate 301 side in the thickness direction D1 of the substrate 301. The solder bump 5 is connected to the metal post 3052 of the columnar electrode 305.

In the radio frequency module 1 according to the present embodiment, as illustrated in FIG. 3, the functional portion 302, the insulating film 303, the pad electrode 304, and the columnar electrode 305 are arranged in this order from the substrate 301 side in the thickness direction D1 of the substrate 301 (thickness direction of the mounting substrate 2).

Further, in the radio frequency module 1 according to the present embodiment, as illustrated in FIG. 3, the solder bump 5 and the functional portion 302 overlap each other in a plan view from the thickness direction D1 of the substrate 301 (thickness direction of the mounting substrate 2).

(3) Main Portion of Radio Frequency Module

Next, a main portion of the radio frequency module 1 according to the present embodiment will be described in comparison with a conventional radio frequency module.

In the conventional radio frequency module, as described above, the entire electronic component 3 is in contact with the resin layer 7, and the space 10 is not provided between the first face 31 of the electronic component 3 and the resin layer 7. In this state, for example, when the radio frequency module is mounted on an external substrate, the thermal stress from the solder bumps 5 causes the stress to act on the electronic component 3 in a direction away from the mounting substrate 2. At this time, since the first face 31 of the electronic component 3 and the resin layer 7 are in contact with each other, the stress directly acts on the electronic component 3, and a crack 100 is generated from the functional portion 302 of the electronic component 3 to the substrate 301 by the stress described above (see FIG. 3). As a result, in the conventional radio frequency module, there is a possibility that the reliability of the electronic component 3 is lowered.

On the other hand, in the radio frequency module 1 according to the present embodiment, since the space 10 is provided between the first face 31 of the electronic component 3 and the resin layer 7, the electronic component 3 moves to the space 10 side with respect to the thermal stress from the solder bump 5, so the stress applied to the electronic component 3 can be reduced. As a result, the crack 100 is less likely to occur in the electronic component 3, and a decrease in the reliability of the electronic component 3 can be suppressed.

Next, as a conventional radio frequency module, a case where a space is provided between the side face 33 of the electronic component 3 and the resin layer 7, and the side face 33 and the resin layer 7 are not in contact with each other is assumed. For example, when a drop impact test conforming to JESD22-B111 and a vibration test conforming to JESD22-B103 are performed on the conventional radio frequency module, the side face 33 and the resin layer 7 are not in contact with each other, and the electronic component 3 is not sufficiently held by the resin layer 7, so the electronic component 3 may be separated from the mounting substrate 2.

On the other hand, in the radio frequency module 1 according to the present embodiment, as illustrated in FIG. 2, the side face 33 of the electronic component 3 and the resin layer 7 are in contact with each other, and the electronic component 3 is held by the resin layer 7. Thus, even when the radio frequency module 1 is subjected to the drop impact test and the vibration test that have been described above, the separation of the electronic component 3 from the mounting substrate 2 can be suppressed.

As a result, according to the radio frequency module 1 of the present embodiment, it is possible to reduce the stress applied to the electronic component 3 when the radio frequency module 1 is mounted on an external substrate while suppressing the separation of the electronic component 3 from the mounting substrate 2. Note that a similar effect can be obtained for the electronic component 4.

(4) Effects

In the radio frequency module 1 according to the present embodiment, as illustrate in FIG. 2, the space 10 is provided between the first face 31 of the electronic component 3 and the resin layer 7 in the thickness direction D1 of the mounting substrate 2. Thus, for example, when the radio frequency module 1 is mounted on an external substrate, even in a case where the thermal stress from the solder bumps 5 is applied to the electronic component 3, the electronic component 3 moves to the space 10 side with respect to the thermal stress, and thus, the stress applied to the electronic component 3 can be reduced. As a result, a decrease in the reliability of the electronic component 3 can be suppressed. Further, the same effect can be obtained for the electronic component 4.

Further, in the radio frequency module 1 according to the present embodiment, as illustrated in FIG. 2, the side face 33 of the electronic component 3 and the resin layer 7 are in contact with each other. As a result, the separation of the electronic component 3 from the mounting substrate 2 can be suppressed compared to a case where the side face 33 of the electronic component 3 and the resin layer 7 are not in contact with each other. Further, the same effect can be obtained for the electronic component 4.

That is, according to the radio frequency module 1 of the present embodiment, it is possible to reduce the stress applied to the electronic components 3 and 4 when the radio frequency module 1 is mounted on an external substrate while suppressing the separation of the electronic components 3 and 4 from the mounting substrate 2.

Also, in the radio frequency module 1 according to the present embodiment, the spaces 10 and 11 are respectively provided between the entire first faces 31 and 41 of the electronic components 3 and 4 and the resin layers 7 and 8 in the thickness direction D1 of the mounting substrate 2. For this reason, it is possible to reduce the stress applied to the electronic components 3 and 4 compared to a case where the spaces 10 and 11 are respectively provided between parts of the first faces 31 and 41 and the resin layers 7 and 8, and thus, it is possible to improve the reliability of the electronic components 3 and 4.

(5) Modifications

Hereinafter, modifications of the above-described embodiment will be described.

(5.1) Modification 1

In the radio frequency module 1 according to the above-described embodiment, as illustrated in FIG. 2, the resin layer 8 is provided on the second main surface 22 side of the mounting substrate 2 so as to cover the electronic component 4 disposed on the second main surface 22. Further, the radio frequency module 1 includes a plurality of external connection terminals 9 formed in a cylindrical shape, and is connected to an external substrate by the plurality of external connection terminals 9.

On the other hand, as in a radio frequency module 1A illustrated in FIG. 4, the resin layer 8 (see FIG. 2) may be omitted on the second main surface 22 side of the mounting substrate 2, and the radio frequency module 1A may be connected to an external substrate by a plurality of external connection terminals 9A formed in a spherical shape. Each of the plurality of external connection terminals 9A is, for example, a ball bump formed in a spherical shape. A material of the ball bump is, for example, gold, copper, solder, or the like. Here, in Modification 1, the first main surface 21 is one main surface.

Moreover, in the radio frequency module 1A according to Modification 1, as illustrated in FIG. 4, the space 10 is provided between the first face 31 of the electronic component 3 and the resin layer 7 in the thickness direction D1 of the mounting substrate 2. Thus, for example, when the radio frequency module 1A is mounted on an external substrate, even in a case where the thermal stress from the solder bumps 5 is applied to the electronic component 3, the electronic component 3 moves toward the space 10 with respect to the thermal stress, and thus, the stress applied to the electronic component 3 can be reduced. As a result, a decrease in the reliability of the electronic component 3 can be suppressed.

Moreover, in the radio frequency module 1A according to Modification 1, as illustrated in FIG. 4, the side face 33 of the electronic component 3 is in contact with the resin layer 7. As a result, the separation of the electronic component 3 from the mounting substrate 2 can be suppressed compared to a case where the side face 33 of the electronic component 3 and the resin layer 7 are not in contact with each other.

That is, according to the radio frequency module 1A of Modification 1, it is possible to reduce the stress applied to the electronic component 3 when the radio frequency module 1A is mounted on an external substrate while suppressing the separation of the electronic component 3 from the mounting substrate 2.

(5.2) Modification 2

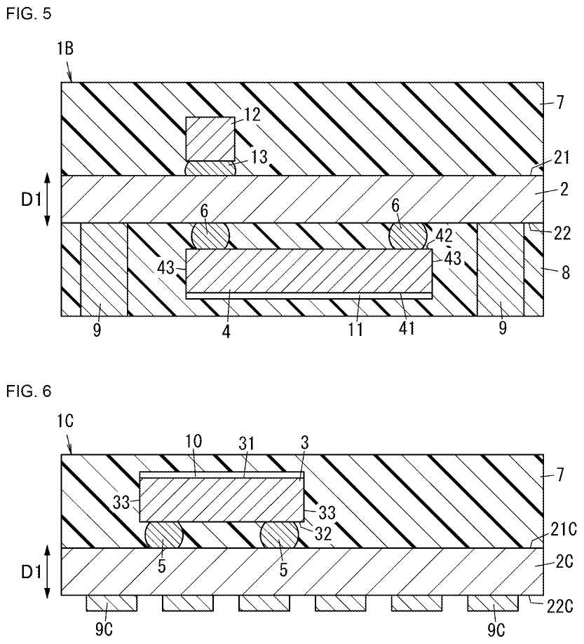

In the radio frequency module 1 according to the above-described embodiment, as illustrated in FIG. 2, the space 10 is provided between the electronic component 3 provided on the first main surface 21 of the mounting substrate 2 and the resin layer 7, and the space 11 is provided between the electronic component 4 provided on the second main surface 22 of the mounting substrate 2 and the resin layer 8. In contrast, as in a radio frequency module 1B illustrated in FIG. 5, the space 11 may be provided only between the electronic component 4 provided on the second main surface 22 of the mounting substrate 2 and the resin layer 8. Hereinafter, the radio frequency module 1B according to Modification 2 will be described with reference to FIG. 5.

As illustrated in FIG. 5, the radio frequency module 1B according to the Modification 2 includes a mounting substrate 2, an electronic component 4, a plurality of solder bumps 6, resin layers 7 and 8, and a plurality of external connection terminals 9. The radio frequency module 1B further includes a matching circuit 12 and a solder layer 13.

In the radio frequency module 1B according to Modification 2, the mounting substrate 2 is a double-sided mounting substrate where circuit elements (the matching circuit 12 and the electronic component 4) are respectively mounted on the first main surface 21 and the second main surface 22, as with the radio frequency module 1 according to the above-described embodiment. Note that configurations other than the matching circuit 12 and the solder layer 13 are similar to those of the radio frequency module 1 according to the above-described embodiment, and a description thereof is omitted here.

The matching circuit 12 includes, for example, at least one inductor. The matching circuit 12 is provided between a low-noise amplifier as the electronic component 4 and a reception filter (not illustrated). The matching circuit 12 performs impedance matching between the low-noise amplifier and the reception filter. The matching circuit 12 is provided on the first main surface 21 of the mounting substrate 2 with the solder layer 13 interposed therebetween.

In the radio frequency module 1B according to Modification 2, the external connection terminals 9 for electrically connecting the radio frequency module 1B to an external substrate is provided on the second main surface 22 of the mounting substrate 2. In other words, the radio frequency module 1B further includes the external connection terminal 9 provided on the second main surface 22 of the mounting substrate 2. In the radio frequency module 1B according to Modification 2, the electronic component 4 is provided on the second main surface 22 of the mounting substrate 2, and the second main surface 22 of the mounting substrate 2 is one main surface.

Furthermore, in the radio frequency module 1B according to Modification 2, as illustrated in FIG. 5, the space 11 is provided between the first face 41 of the electronic component 4 and the resin layer 8 in the thickness direction D1 of the mounting substrate 2. Thus, for example, when the radio frequency module 1B is mounted on an external substrate, even in a case where the thermal stress from the solder bumps 5 is applied to the electronic component 4, the electronic component 4 moves toward the space 11 with respect to the thermal stress, and thus, the stress applied to the electronic component 4 can be reduced. As a result, a decrease in the reliability of the electronic component 4 can be suppressed.

In addition, in the radio frequency module 1B according to Modification 2, as illustrated in FIG. 5, the side face 43 of the electronic component 4 is in contact with the resin layer 8. As a result, it is possible to suppress the separation of the electronic component 4 from the mounting substrate 2 compared to a case where the side face 43 of the electronic component 4 and the resin layer 8 are not in contact with each other.

That is, according to the radio frequency module 1B of Modification 2, it is possible to reduce the stress applied to the electronic component 4 when the radio frequency module 1B is mounted on an external substrate while suppressing the separation of the electronic component 4 from the mounting substrate 2.

Note that in the radio frequency module 1B according to Modification 2, the space 11 is provided only on the second main surface 22 side of the mounting substrate 2, but the space may be provided only on the first main surface 21 side of the mounting substrate 2. That is, with respect to the mounting substrate 2 that is a double-sided mounting substrate, the space may be provided only on the first main surface 21 side or the space 11 may be provided only on the second main surface 22 side.

(5.3) Modification 3

In the radio frequency module 1 according to the above-described embodiment, the circuit elements (electronic components 3 and 4) are respectively mounted on the first main surface 21 and the second main surface 22 of the mounting substrate 2, but as in a radio frequency module 1C illustrated in FIG. 6, the electronic component 3 may be mounted only on a first main surface 21C of a mounting substrate 2C. Hereinafter, the radio frequency module 1C according to Modification 3 will be described with reference to FIG. 6. In the following description, components similar to those of the radio frequency module 1 according to the above-described embodiment are denoted by the same reference signs, and a description thereof will be omitted.

As illustrated in FIG. 6, the radio frequency module 1C according to Modification 3 includes the mounting substrate 2C, the electronic component 3, a plurality of solder bumps 5, the resin layer 7, and a plurality of external connection terminals 9C.

As illustrated in FIG. 6, the mounting substrate 2C is a mounting substrate formed in a rectangular plate shape. The mounting substrate 2C has a first main surface 21C and a second main surface 22C. The first main surface 21C and the second main surface 22C are opposed to each other in the thickness direction D1 of the mounting substrate 2C. In the radio frequency module 1C according to Modification 3, the electronic component 3 is mounted only on the first main surface 21C of the mounting substrate 2C. That is, the mounting substrate 2C is a single-sided mounting substrate where the electronic component 3 is mounted only on the first main surface 21C. In Modification 3, the first main surface 21 of the mounting substrate 2 is one main surface.

The plurality of external connection terminals 9C is disposed on the second main surface 22C of the mounting substrate 2C. Each of the plurality of external connection terminals 9C is, for example, a land grid array (LGA) covered with gold plating. Each LGA is, for example, a solder bump. The LGA may be, for example, a ball grid array (BGA) such as a solder bump or a gold bump. The radio frequency module 1C is connected to an external substrate (not illustrated) through the plurality of external connection terminals 9C.

Moreover, in the radio frequency module 1C according to Modification 3, as illustrated in FIG. 6, the space 10 is provided between the first face 31 of the electronic component 3 and the resin layer 7 in the thickness direction D1 of the mounting substrate 2C. Thus, for example, when the radio frequency module 1C is mounted on an external substrate, even in a case where the thermal stress from the solder bumps 5 is applied to the electronic component 3, the electronic component 3 moves toward the space 10 with respect to the thermal stress, and thus, the stress applied to the electronic component 3 can be reduced. As a result, a decrease in the reliability of the electronic component 3 can be suppressed.

Furthermore, in the radio frequency module 1C according to Modification 3, as illustrated in FIG. 6, the side face 33 of the electronic component 3 is in contact with the resin layer 7. As a result, it is possible to suppress the separation of the electronic component 3 from the mounting substrate 2C compared to a case where the side face 33 of the electronic component 3 is not in contact with the resin layer 7.

That is, according to the radio frequency module 1C of Modification 3, it is possible to reduce the stress applied to the electronic component 3 when the radio frequency module 2C is mounted on an external substrate while suppressing the separation of the electronic component 3 from the mounting substrate 1C.

In Modification 3, although the external connection terminal 9C is the LGA, the external connection terminal 9C is not limited to the LGA, and may be, for example, an electrode having a cylindrical shape as with the radio frequency module 1 according to the above-described embodiment.

(Aspects)

The following aspects are disclosed from the embodiment and the like described above.

A radio frequency module (1; 1A; 1B; 1C) according to a first aspect includes a mounting substrate (2; 2C), electronic components (3, 4), solder bumps (5, 6), and resin layers (7, 8). The mounting substrate (2; 2C) has one main surface (21, 22). The electronic components (3, 4) have a first face (31, 41) and a second face (32, 42) that are opposed to each other, and a side face (33, 43), and are provided on one main surface (21, 22) of the mounting substrate (2; 2C). The side face (33, 43) intersects the first face (31, 41) and the second face (32, 42). The solder bumps (5, 6) are disposed between the mounting substrate (2; 2C) and the electronic components (3, 4), and electrically connect the mounting substrate (2) and the electronic components (3, 4). The resin layer (7, 8) is provided on the one main surface (21, 22) of the mounting substrate (2; 2C) so as to cover the electronic component (3, 4). The first face (31, 41) is a face of the electronic component (3, 4) at an opposite side to the mounting substrate (2; 2C). The side face (33, 43) of the electronic component (3, 4) is in contact with the resin layer (7, 8). A space (10, 11) is provided between at least a part of the first face (31, 41) and the resin layer (7, 8) in the thickness direction (D1) of the mounting substrate (2; 2C).

According to this aspect, it is possible to reduce the stress applied to the electronic component (3, 4) when the radio frequency module (1; 1A; 1B; 1C) is mounted on an external substrate while suppressing the separation of the electronic component (3, 4) from the mounting substrate (2; 2C).

In the radio frequency module (1; 1A; 1B; 1C) according to the second aspect, in the first aspect, at least a part of the first face (31, 41) overlaps the solder bump (5, 6) in a plan view from the thickness direction (D1) of the mounting substrate (2; 2C).

According to this aspect, it is possible to reduce the stress applied to the electronic component (3, 4) when the radio frequency module (1; 1A; 1B; 1C) is mounted on an external substrate while suppressing the separation of the electronic component (3, 4) from the mounting substrate (2; 2C).

In the radio frequency module (1; 1A; 1B; 1C) according to a third aspect, in the first or second aspect, the space (10, 11) is provided between the entire first face (31, 41) and the resin layer (7, 8) in the thickness direction (D1) of the mounting substrate (2; 2C).

According to this aspect, it is possible to reduce the stress applied to the electronic component (3, 4) when the radio frequency module (1; 1A; 1B; 1C) is mounted on an external substrate, compared to a case where the space (10, 11) is provided between a part of the first face (31, 41) and the resin layer (7, 8).

The radio frequency module (1B) according to a fourth aspect, in any one of the first to third aspects, further includes an external connection terminal (9). The external connection terminal (9) is provided on the one main surface (22) of the mounting substrate (2).

According to this aspect, it is possible to reduce the stress applied to the electronic component (4) when the radio frequency module (1B) is mounted on an external substrate, while suppressing the separation of the electronic component (4) from the mounting substrate (2).

In the radio frequency module (1) according to a fifth aspect, in any one of the first to fourth aspects, the electronic component (3) includes a functional portion (302) provided on the second face (32). In the radio frequency module (1), the solder bump (5) and the functional portion (302) overlap each other in a plan view from the thickness direction (D1) of the mounting substrate (2).

According to this aspect, it is possible to reduce the influence of the thermal stress from the solder bump (5) on the functional portion (302).

In the radio frequency module (1) according to a sixth aspect, in any one of the first to fourth aspects, the electronic component (3) includes a base portion (for example, a substrate 301) and a functional portion (302) provided on the base portion. The base portion contains gallium arsenide, silicon germanium, silicon, silicon carbide or gallium nitride.

According to this aspect, it is possible to suppress the occurrence of a crack (100) in the base portion due to the thermal stress from the solder bump (5).

In the radio frequency module (1) according to a seventh aspect, in any one of the first to fourth aspects, the electronic component (3) includes the substrate (301), the functional portion (302), an insulating film (303), a pad electrode (304), and a columnar electrode (305). The functional portion (302) is provided on the substrate (301). The insulating film (303) is provided on the substrate (301) so as to cover the functional portion (302). The pad electrode (304) is electrically connected to the functional portion (302). The columnar electrode (305) electrically connects the pad electrode (304) and the solder bump (5). In the radio frequency module (1), the insulating film (303), the pad electrode (304), and the columnar electrode (305) are arranged in this order from the substrate (301) side in the thickness direction (D1) of the mounting substrate (2).

In the radio frequency module (1; 1A; 1B; 1C) according to an eighth aspect, in any one of the first to seventh aspects, the electronic component (3, 4) is flip-chip mounted on the one main surface (21, 22) of the mounting substrate (2, 2C) with the solder bump (5, 6) interposed therebetween.

In the radio frequency module (1; 1A; 1B) according to a ninth aspect, in any one of the first to eighth aspects, the electronic component (4) is a low-noise amplifier that amplifies a reception signal from an antenna.

In the radio frequency module (1; 1A; 1C) according to a tenth aspect, in any one of the first to eighth aspects, the electronic component (3) is a power amplifier that amplifies a transmission signal to an antenna.

In the radio frequency module (1; 1A; 1B; 1C) according to an eleventh aspect, in any one of the first to tenth aspects, the resin layer (7, 8) contains epoxy resin, phenol resin, urethane resin, or polyimide.

In the radio frequency module (1; 1A; 1B; 1C) according to a twelfth aspect, in any one of the first to eleventh aspects, the mounting substrate (2; 2C) is a printed circuit board or a ceramic substrate.
1, 1A, 1B, 1C RADIO FREQUENCY MODULE
2, 2C MOUNTING SUBSTRATE
3, 4 ELECTRONIC COMPONENT
5, 6 SOLDER BUMP
7, 8 RESIN LAYER
9, 9A, 9C EXTERNAL CONNECTION TERMINAL
10, 11 SPACE
12 MATCHING CIRCUIT
13 SOLDER LAYER
21, 21C FIRST MAIN SURFACE (ONE MAIN SURFACE)
22, 22C SECOND MAIN SURFACE (ONE MAIN SURFACE)
31 FIRST FACE
32 SECOND FACE
33 SIDE FACE
41 FIRST FACE
42 SECOND FACE
43 SIDE FACE
100 CRACK
301 SUBSTRATE
302 FUNCTIONAL PORTION
303 INSULATING FILM
304 PAD ELECTRODE
3021 SUB-COLLECTOR LAYER
3022 COLLECTOR LAYER
3023 BASE LAYER
3024 EMITTER LAYER
3025 EMITTER MESA LAYER
3041 EMITTER ELECTRODE
3042 EMITTER WIRING LINE
3043 BASE ELECTRODE
3044 BASE WIRING LINE
3051 UNDER BUMP METAL LAYER
3052 METAL POST
D1 THICKNESS DIRECTION

1. A radio frequency module comprising:
a mounting substrate having one main surface;
an electronic component having a first face, a second face and a side face, the first face and the second face being opposed to each other and the side face intersecting with the first face and the second face, the electronic component being provided on the one main surface of the mounting substrate;
a solder bump disposed between the mounting substrate and the electronic component and electrically connecting the mounting substrate and the electronic component; and
a resin layer provided on the one main surface of the mounting substrate to cover the electronic component,
wherein the first face is a face of the electronic component at a side opposite to the mounting substrate,
the side face of the electronic component and the resin layer are in contact with each other, and
a space is provided between at least a part of the first face and the resin layer in a thickness direction of the mounting substrate.

2. The radio frequency module according to claim 1,
wherein at least a part of the first face overlaps the solder bump in a plan view from the thickness direction of the mounting substrate.

3. The radio frequency module according to claim 1,
wherein the space is provided between an entire portion of the first face and the resin layer in the thickness direction of the mounting substrate.

4. The radio frequency module according to claim 1, further comprising:
an external connection terminal provided on the one main surface of the mounting substrate.

5. The radio frequency module according to claim 1,
wherein the electronic component includes
a functional portion provided on the second face, and
the solder bump and the functional portion overlap each other in a plan view from the thickness direction of the mounting substrate.

6. The radio frequency module according to claim 1,
wherein the electronic component includes
a base portion, and
a functional portion provided on the base portion, and
the base portion contains gallium arsenide, silicon germanium, silicon, silicon carbide or gallium nitride.

7. The radio frequency module according to claim 1,
wherein the electronic component includes
a substrate,
a functional portion provided on the substrate,
an insulating film provided on the substrate to cover the functional portion,
a pad electrode electrically connected to the functional portion, and
a columnar electrode electrically connecting the pad electrode and the solder bump, and
the insulating film, the pad electrode, and the columnar electrode are arranged in this order from a side of the substrate in the thickness direction of the mounting substrate.

8. The radio frequency module according to claim 1,
wherein the electronic component is flip-chip mounted on the one main surface of the mounting substrate with the solder bump interposed between the electronic component and the one main surface of the mounting substrate.

9. The radio frequency module according to claim 1,
wherein the electronic component is a low-noise amplifier configured to amplify a reception signal from an antenna.

10. The radio frequency module according to claim 1,
wherein the electronic component is a power amplifier configured to amplify a transmission signal to an antenna.

11. The radio frequency module according to claim 1,
wherein the resin layer contains epoxy resin, phenol resin, urethane resin, or polyimide.

12. The radio frequency module according to claim 1,
wherein the mounting substrate is a printed circuit board or a ceramic substrate.

13. The radio frequency module according to claim 2,
wherein the space is provided between an entire portion of the first face and the resin layer in the thickness direction of the mounting substrate.

14. The radio frequency module according to claim 2, further comprising:
an external connection terminal provided on the one main surface of the mounting substrate.

15. The radio frequency module according to claim 3, further comprising:
an external connection terminal provided on the one main surface of the mounting substrate.

16. The radio frequency module according to claim 2,
wherein the electronic component includes
a functional portion provided on the second face, and
the solder bump and the functional portion overlap each other in a plan view from the thickness direction of the mounting substrate.

17. The radio frequency module according to claim 3,
wherein the electronic component includes
a functional portion provided on the second face, and the solder bump and the functional portion overlap each other in a plan view from the thickness direction of the mounting substrate.

18. The radio frequency module according to claim 4,
wherein the electronic component includes
a functional portion provided on the second face, and
the solder bump and the functional portion overlap each other in a plan view from the thickness direction of the mounting substrate.

19. The radio frequency module according to claim 2,
wherein the electronic component includes
a base portion, and
a functional portion provided on the base portion, and
the base portion contains gallium arsenide, silicon germanium, silicon, silicon carbide or gallium nitride.

20. The radio frequency module according to claim 3,
wherein the electronic component includes
a base portion, and
a functional portion provided on the base portion, and
the base portion contains gallium arsenide, silicon germanium, silicon, silicon carbide or gallium nitride.
